(19) United States
(12) Patent Application Publication
(10) Pub. No.: US 2024/0199306 A1
(43) Pub. Date: Jun. 20, 2024

(54) Multifunctional Insulated Cooler Apparatus

(71) Applicants: Clifton A Downie, Jr., Snellville, GA (US); Ravi Y Navare, Mableton, GA (US)

(72) Inventors: Clifton A Downie, Jr., Snellville, GA (US); Ravi Y Navare, Mableton, GA (US)

(21) Appl. No.: 18/581,355

(22) Filed: Feb. 19, 2024

Related U.S. Application Data
(60) Provisional application No. 63/476,116, filed on Dec. 19, 2022.

(51) Int. Cl. B65D 81/38; H05K 5/00

(52) U.S. Cl. CPC B65D 81/3813; H05K 5/0086; B65D 2201/00

(57) ABSTRACT

A multifunctional insulated cooler apparatus includes an insulated compartment, a lid, a rechargeable power source, and at least one speaker system. The insulated compartment includes a base, a lateral wall, and an opening so that the insulated compartment is able to provide a cold storage area for food items and beverages. The lateral wall is perimetrically connected around the base as the opening is delineated by the lateral wall, opposite of the base. The lid is perimetrically attached to the lateral wall about the opening so that the stored items can be enclosed. The rechargeable power source is mounted within the lid thus allowing the users to recharge mobile phones and other related electrical devices. The speaker system is integrated into the lid and electrically connected to the rechargeable power source thus allowing the user to play music and other sound outputs.

The current application claims a priority to the U.S. provisional patent application Ser. No. 63/476,116 filed on Dec. 19, 2022. The U.S. provisional patent application 63/476,116 is revived within the two-month period for unintentional abandonment by Feb. 19, 2024.

### FIELD OF THE INVENTION

The present invention relates generally to an insulated cooler. More specifically, the present invention is a multifunctional insulated cooler apparatus for cooling food and beverage items while functioning as a portable speaker unit and a portable power source.

### BACKGROUND OF THE INVENTION

An insulated cooler, also known as coolers or ice box, is generally used to keep food or beverage items cool. More specifically, ice cubes or ice packs are placed within the cooler in order to maintain a cold environment. As a result, stored contents within the cooler can also stay cold for extended period of time. Coolers are often taken on picnics, vacations, or holidays to transport cold groceries, food items, or beverage items. For example, the coolers are generally used to transport ice cream during hot summer days thus preventing the ice cream from melting. Coolers are usually made with interior and exterior shells of plastic with a hard foam in between the interior and exterior shells. Most of the coolers are configured with handles and/or wheels to ease transportation and cup holders to secure beverage items. Other than the aforementioned features, the existing coolers generally do not have other functional features.

It is therefore an objective of the present invention to provide a multifunctional insulated cooler apparatus for cooling food and beverage items. More specifically, the present invention is configured with a portable power source so that the users can use an integrated speaker unit and recharge portable electric devices such as mobile phones and computers. Furthermore, the present invention is configured with a removable plate that is capable of creating separate storage spaces. The present invention can also be customized to snuggly fit into the trunk area of front-wheel vehicles, the front storage area of a mid-engine rear-wheel vehicles, or the trunk and the front storage area of electric vehicles.

### BRIEF DESCRIPTION OF THE DRAWINGS

FIG. 1 is a top perspective view of the present invention.

FIG. 2 is a top view of the present invention, wherein the dash lines illustrate the internally mounted components of the lid.

FIG. 3 is a top exploded view of the present invention.

FIG. 4 is a front view of the present invention.

FIG. 5 is a right view of the insulated compartment of the present invention.

FIG. 6 is a top perspective view of the insulated compartment of the present invention.

FIG. 7 is a top view of the insulated compartment of the present invention.

FIG. 8 is a top exploded view of the insulated compartment and the divider plate of the present invention.

FIG. 9 is a schematic view showing the electrical connections of the present invention.

FIG. 10 is a schematic view of the electronic connections of the present invention.

### DETAILED DESCRIPTION OF THE INVENTION

All illustrations of the drawings are for the purpose of describing selected versions of the present invention and are not intended to limit the scope of the present invention.

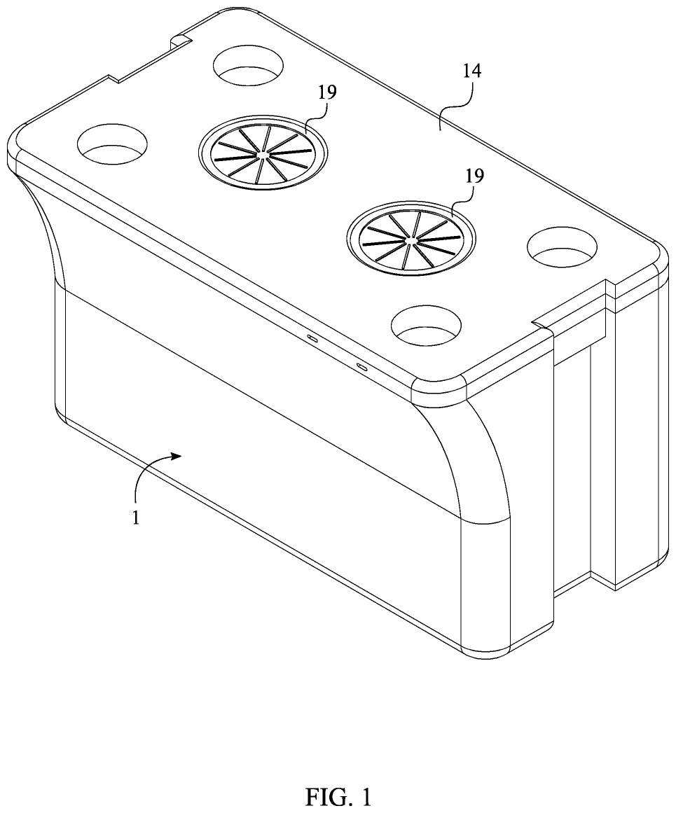

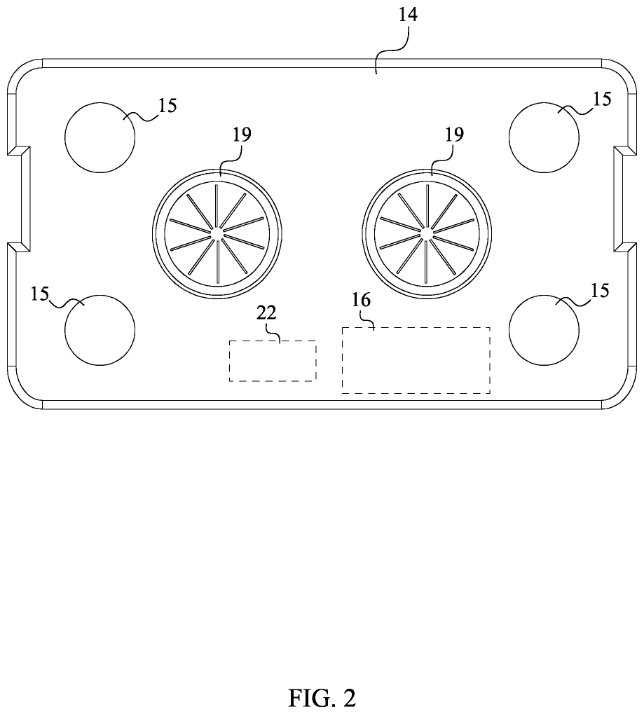

The present invention is a multifunctional insulated cooler apparatus for cooling food and beverage items. The present invention allows the user to keep food items, beer, wine, beverages, water, and other related items cold when stored within the present invention. The cooling process of the present invention is similar to existing coolers as ice cubes or ice packs reduce the storage temperature of the present invention. As shown in FIG. 1 and FIG. 2, the present invention comprises an insulated compartment 1, a lid 14, a rechargeable battery 16, and at least one speaker system 19.

In reference to the general configuration of the present invention, as shown in FIGS. 1-3 and FIG. 9, the insulated compartment 1 that functions as storage compartment for food items and beverages comprises a base 2, a lateral wall 3, and an opening 11. More specifically, the lateral wall 3 is perimetrically connected around the base 2 thus forming the general shape of the insulated compartment 1. The opening 11 is delineated by the lateral wall 3 and positioned opposite of the base 2 so that the users can access the storage area of the insulated compartment 1. The lid 14 is perimetrically attached to the lateral wall 3 about the opening 11 and fully encloses the insulated compartment 1. The rechargeable battery 16 is mounted within the lid 14 to protect the rechargeable battery 16 from outside elements. The speaker system 19 is integrated into the lid 14 and functions as an audio player. In order to power the speaker system 19, the speaker system 19 is electrically connected to the rechargeable battery 16, wherein the rechargeable battery 16 provides the necessary electrical power to the speaker system 19.

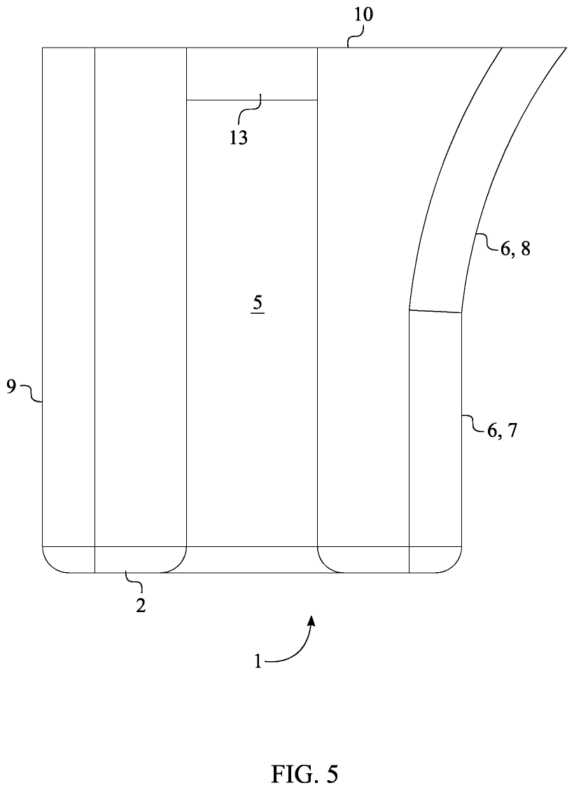

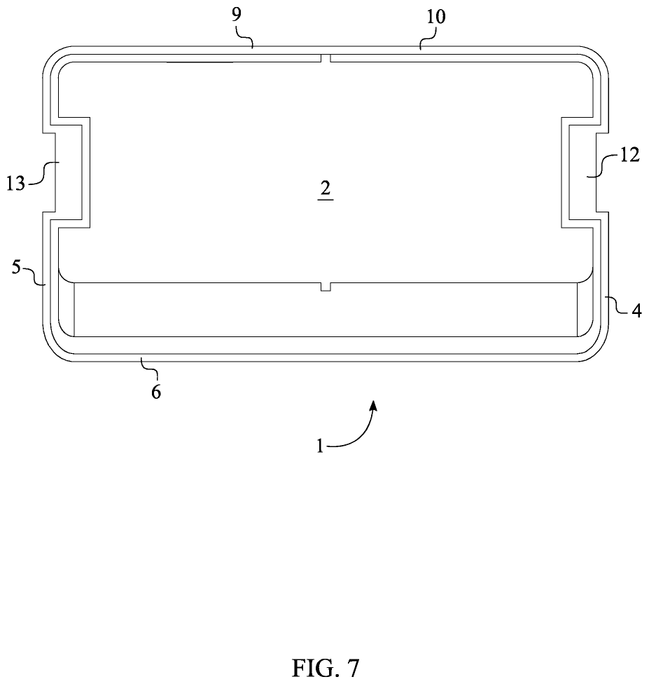

In reference to FIGS. 5-7, the insulated compartment 1 is generally formed into a rectangular shape as the lateral wall 3 may comprise a left wall 4, a right wall 5, a front wall 6, a rear wall 9, and a top edge 10. The base 2 functions as the bottom layer of the insulated compartment 1 as the lateral wall 3 is perimetrically connected around the base 2. More specifically, the left wall 4 and the right wall 5 are terminally connected to the base 2 in such a way that the left wall 4 and the right wall 5 are oppositely positioned of each other about the base 2. The front wall 6 is terminally connected to the base 2, the left wall 4, and the right wall 5 so that the front end of the insulated compartment 1 can be enclosed. Similarly, the rear wall 9 is terminally connected to the base 2, the left wall 4, and the right wall 5 thus enclosing the rear end of the insulated compartment 1. The front wall 6 and the rear wall 9 are oppositely positioned of each other about the base 2 so that the lateral wall 3 is able to define the storage compartment height of the insulated compartment 1. The top edge 10 is delimited by the left wall 4, the right wall 5, the front wall 6, and the rear wall 9 as the opening 11 is delineated within the top edge 10. As a result, the lid 14 is able to position atop the top edge 10 and fully encloses the insulated compartment 1. Even though the insulated compartment 1 is formed into a rectangular shape, the insulated compartment 1 can be shaped into any other gematric shape without deviating from the scope of the functionality.

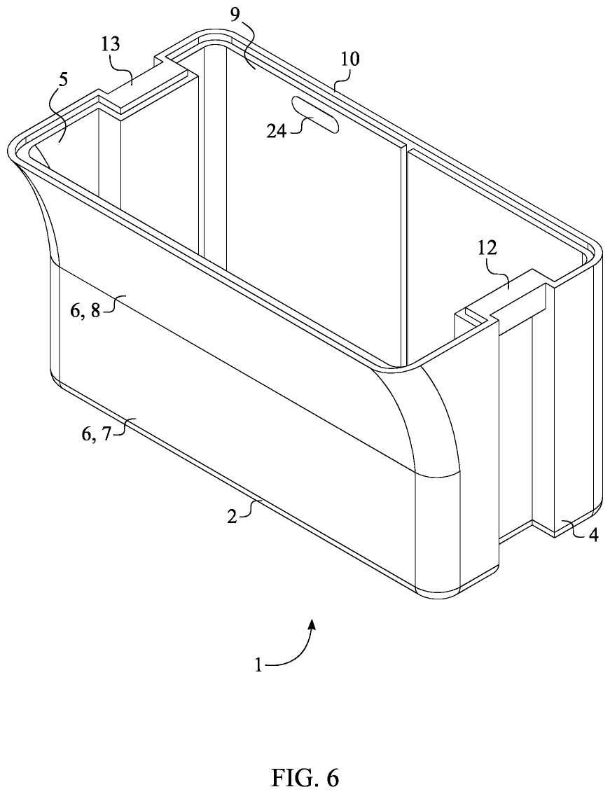

The front wall 6 is preferably configured within the present invention so that the insulated compartment 1 can snuggly fit into specific areas such as the trunk area of front-wheel vehicles, the front storage area of a mid-engine rear-wheel vehicle, the trunk and the front storage area of electric vehicles, or a frunk of the vehicle. In reference to FIG. 5 and FIG. 6, the front wall 6 may comprise a flat section 7 and a curved section 8 so that the front wall 6 can be slightly curved about the top edge 10. More specifically, the flat section 7 is terminally connected to the base 2, the left wall 4, and the right wall 5. The curved section 8 is terminally connected to the flat section 7, the left wall 4, and the right wall 5 as the lid 14 is positioned adjacent to the curved section 8. As a result, the front wall 6 upwardly extends from the base 2 and orients outward from the rear wall 9 so that the front wall 6 can be firmly positioned against a curved vehicular panel. The preferred shape of the front wall 6 is designed to fit exclusively in 2020 and up Chevrolet Corvette C8 models-Stingray models.

In reference to a preferred embodiment of the insulated compartment 1, the overall height of the insulated compartment 1 is delineated from the base 2 to the top edge 10. The length of the insulated compartment 1 is delineated from left wall 4 to the right wall 5. The bottom-depth of the insulated compartment 1 is delineated from the flat section 7 of the front wall 4 to the rear wall 9. The top-depth of the insulated compartment 1 is delineated from the curved section 8 of the front wall 4 to the rear wall 9.

In order to precisely fit into the frunk area of the 2020 and up Chevrolet Corvette C8 models-Stingray models, the overall height is measured to be approximately 12.5 inches, the length is measured to be approximately 23.75 inches, the bottom-depth is measured to be approximately 10.5 inches, and the top-depth is measured to be approximately 12.25-12.5 inches. Furthermore, the sectional height of the flat section 7 is delineated from the base 2 to the break-point of the front wall 4 as the break-point differentiates the flat section 7 from the curved section 8. The sectional height of the flat section 7 is measured to be approximately 9-9.25 inches.

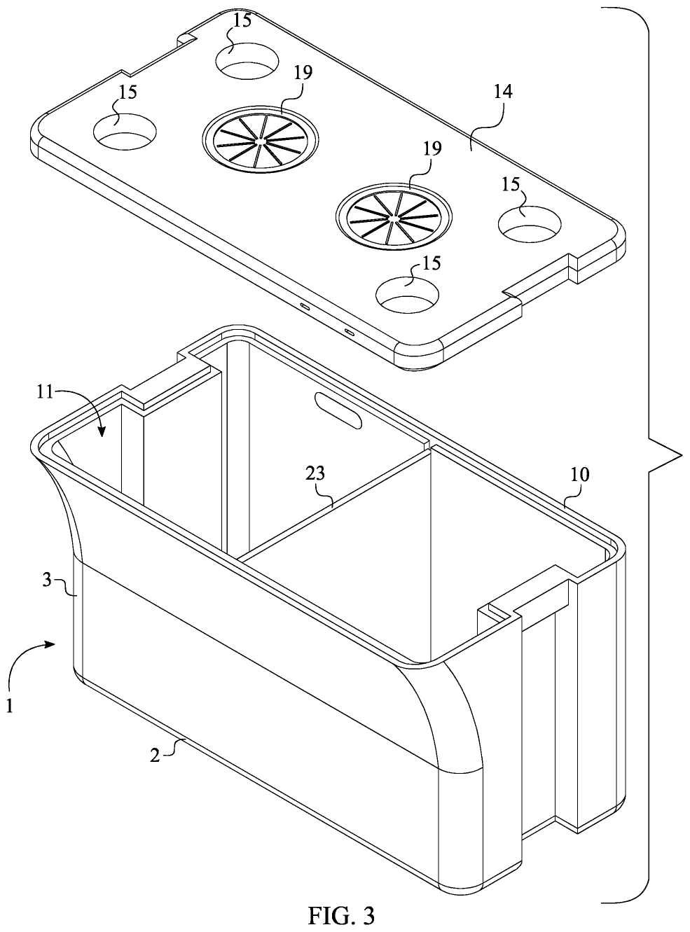

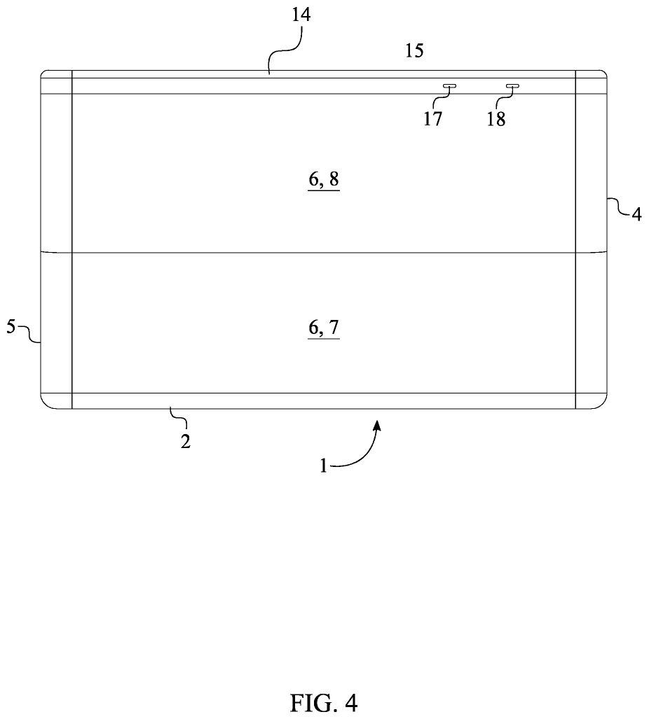

In reference to FIG. 3 and FIG. 4, the lid 14 is formed into a rectangular shape to fully enclose the opening 11 of the insulated compartment 1. Even though the lid 14 is formed into a rectangular shape, the lid 14 can be shaped into any other gematric shape as long as the shape of the lid 14 is able to fully enclose the opening 11 of the insulated compartment 1. Furthermore, the lid 14 also functions as a mounting body for the functional features of the present invention. The lid can also function as a food serving tray, a platform to place a mobile computing device, or a rigid platform that can elevate any related items.

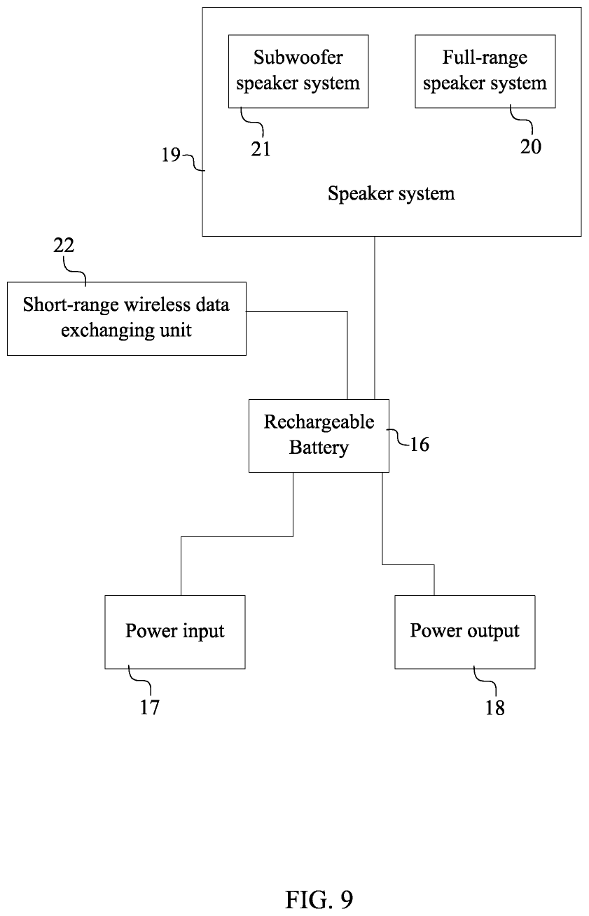

In reference to FIG. 2 and FIG. 9, the rechargeable battery 16 is mounted within the lid 14 and functions as the primary power source of the present invention. Preferably, a lithium ion battery 16 is utilized within to optimize the operation of the present invention. As mentioned before, the rechargeable battery 16 is electrically connected to the speaker system 19 so that the speaker system 19 can be electrically powered and operational. The present invention may further comprise a power input 17 and power output 18 as shown in FIG. 4 and FIG. 9. The power input 17 and the power output 18 are integrated into the lid 14 so that the user can easily access the power input 17 and the power output 18. More specifically, the power input 17 is electrically connected to the rechargeable battery 16 in order to recharge the rechargeable battery 16 from an external power source. For example, the power input 17 can be electrically connected with a vehicular power-output via a power cable to recharge the rechargeable battery 16. The power output 18 is electrically connected to the rechargeable battery 16 so that the user is able to use the rechargeable battery 16 as a potable power source. For example, the user can plug in a mobile phone, a computer, or any other electronic devices that are powered through a direct current source into the rechargeable battery 16 through the power output 18.

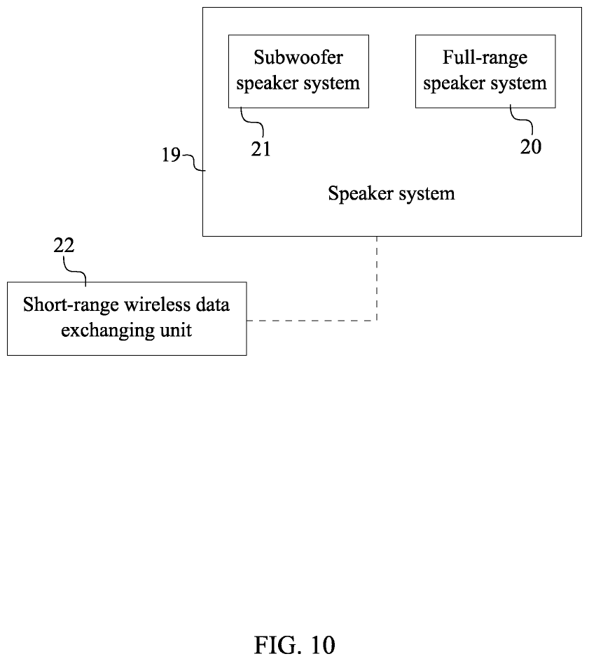

In reference to FIG. 2, FIG. 9, and FIG. 10, the present invention may further comprise a short-range wireless data exchanging unit 22 to communicate with mobile devices or software applications with reference to the speaker system 19. The short-range wireless data exchanging unit 22 is mounted within the lid 14 to protect from outside elements. The short-range wireless data exchanging unit 22 is electrically connected to the rechargeable battery 16 so that the short-range wireless data exchanging unit 22 can be electrically powered and operational. The speaker system 19 is electronically connected to the short-range wireless data exchanging unit 22 thus allowing the user to activate and control the speaker system 19 via mobile devices or software applications.

In reference to FIG. 9, the speaker system 19 of the present invention can be a full-range speaker system 20 that is fully capable of emitting the full audio spectrum. When the present invention is configured with the full-range speaker system 20, the user can utilize the present invention as a portable speaker unit without the usage of an external power source. In reference to FIG. 1, the speaker system 19 of the present invention can also be a subwoofer speaker system 21 that is capable of emitting the lowest-pitched part of the audio spectrum. When the present invention is configured with the subwoofer speaker system 21, the user can utilize the present invention as an additional speaker unit within the vehicle to enhance the vehicular sound system.

In reference to FIGS. 5-7, the present invention may further comprise a left handle 12 and a right handle 13. The left handle 12 and the right handle 13 are utilized to easily transport the insulated compartment 1. More specifically, the left handle 12 is integrated into the left wall 4 of the lateral wall 3. The right handle 13 is integrated into the right wall 5 of the lateral wall 3. As a result, the left handle 12 and the right handle 13 provide two separate grasping area to lift, transport, or move the insulated compartment 1.

In reference to FIG. 2 and FIG. 3, the present invention may further comprise at least one beverage holder 15. The beverage holder 15 is integrated onto the lid 14 and oriented away from the insulated compartment 1. Preferably, the present invention is configured with two or more beverage holder 15s to secure multiple beverages. In other words, the beverage holder 15 functions as a recessed cavity that holds a beverage can, a glass, a wine glass, or any other beverage container.

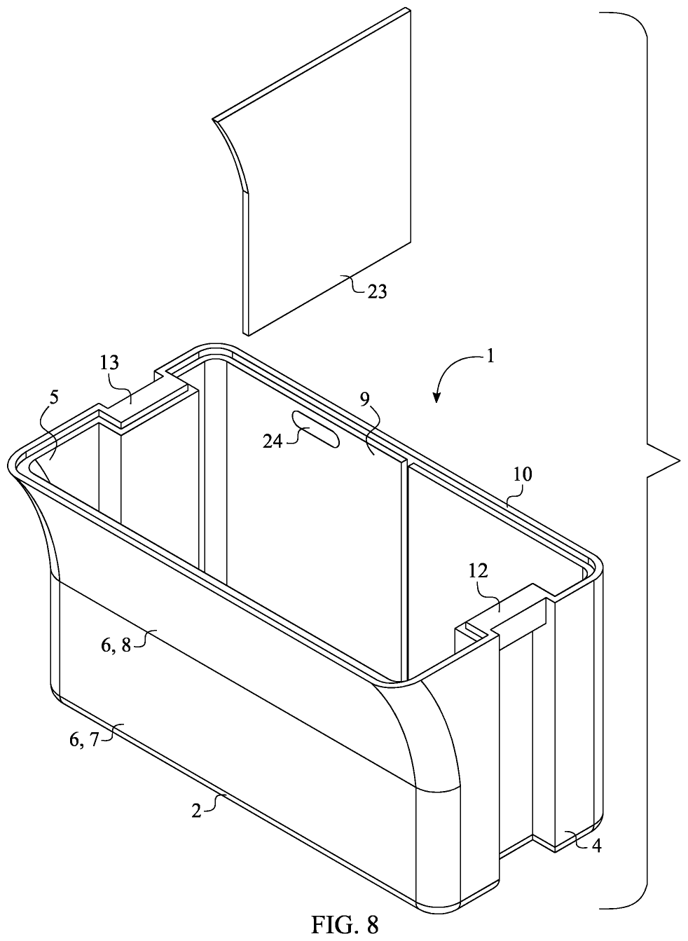

In reference to FIG. 3 and FIG. 8, the present invention may further comprise a divider plate 23. The divider plate 23 is positioned within the insulated compartment 1 and removably engaged with the front wall 6 and the rear wall 9. More specifically, the divider plate 23 can be removably engaged with the front wall 6 and the rear wall 9 through a first channel and a second channel or a first rail and a second rail. When the first channel and the second channel are used within the insulated compartment 1, the divider plate 23 slides into the first channel and the second channel as the first channel internally traverses into front wall 6 and the second channel internally traverses into the rear wall 9. When the first rail and the second rail are used within the insulated compartment 1, the divider plate 23 slides within the first rail and the second rail as the first rail internally connected onto front wall 6 and the second rail internally connected onto the rear wall 9. As a result, the divider plate 23 is able to create two separate storage spaces within the insulated compartment 1. Furthermore, the divider plate 23 can also function as a cutting board when removed from the insulated compartment 1.

In reference to FIG. 8, the present invention may further comprise a thermometer 24 so that the internal temperature of the insulated compartment 1 can be continuously measured. More specifically, the thermometer 24 is positioned within the insulated compartment 1 and adjacently connected onto the lateral wall 3. Preferably, the thermometer 24 is positioned adjacent to the top edge 10 so that the user can easily view the reading of the thermometer 24. It is understood that the thermometer 24 can also be externally connected to the lateral wall 3 without deviating from the scope of the functionality.

The outer layer of the insulated compartment 1 and the lid 14 are preferably made of a tough high-density Polymer such as Polyurethane, Polyurea combination, High Density Polyethylene, or Linear low-density polyethylene. The core of the insulated compartment 1 and the lid 14 are preferably made of low-density hybrid foam with close cell structure. Special processing and chemistry bonding of the manufactured material allow for very low conductivity and very high insulation values for the insulated compartment 1 and the lid 14.

The insulated compartment 1 and the lid 14 can be painted to color match any vehicular color or most custom colors. The insulated compartment 1 and the lid 14 can also be finished with carbon fiber appearance, collegiate colors, logos, and a vast variety of marketing ideas and logos.

Although the invention has been explained in relation to its preferred embodiment, it is to be understood that many other possible modifications and variations can be made without departing from the spirit and scope of the invention as hereinafter claimed.

What is claimed is:

1. A multifunctional insulated cooler apparatus comprising:
an insulated compartment;
a lid;
a rechargeable battery;
at least one speaker system;
the insulated compartment comprising a base, a lateral wall, and an opening;
the lateral wall being perimetrically connected around the base;
the opening being delineated by the lateral wall, opposite of the base;
the lid being perimetrically attached to the lateral wall about the opening;
the rechargeable battery being mounted within the lid;
the speaker system being integrated into the lid; and
the speaker system being electrically connected to the rechargeable battery.

2. The multifunctional insulated cooler apparatus as claimed in claim 1 comprising:
the lateral wall comprising a left wall, a right wall, a front wall, a rear wall, and a top edge;
the left wall being terminally connected to the base;
the right wall being terminally connected to the base;
the left wall and the right wall being oppositely positioned of each other about the base;
the front wall being terminally connected to the base, the left wall, and the right wall;
the rear wall being terminally connected to the base, the left wall, and the right wall;
the front wall and the rear wall being oppositely positioned of each other about the base;
the top edge being delimited by the left wall, the right wall, the front wall, and the rear wall; and
the lid being positioned atop the top edge.

3. The multifunctional insulated cooler apparatus as claimed in claim 2 comprising:
the front wall comprising a flat section and a curved section;
the flat section being terminally connected to the base, the left wall, and the right wall;
the curved section being terminally connected to the flat section, the left wall, and the right wall; and
the lid being positioned adjacent to the curved section.

4. The multifunctional insulated cooler apparatus as claimed in claim 1 comprising:
a power input;
a power output;
the power input being integrated into the lid;
the power output being integrated into the lid;
the power input being electrically connected to the rechargeable battery; and
the power output being electrically connected to the rechargeable battery.

5. The multifunctional insulated cooler apparatus as claimed in claim 1 comprising:
a short-range wireless data exchanging unit;
the short-range wireless data exchanging unit being mounted within the lid;
the short-range wireless data exchanging unit being electrically connected to the rechargeable battery; and
the speaker system being electronically connected to the short-range wireless data exchanging unit.

6. The multifunctional insulated cooler apparatus as claimed in claim 5, wherein the speaker system is a full-range speaker system.

7. The multifunctional insulated cooler apparatus as claimed in claim 5, wherein the speaker system is a subwoofer speaker system.

8. The multifunctional insulated cooler apparatus as claimed in claim 1 comprising:
a left handle;
a right handle;
the left handle being integrated into a left wall of the lateral wall; and
the right handle being integrated into a right wall of the lateral wall.

9. The multifunctional insulated cooler apparatus as claimed in claim 1 comprising:
at least one beverage holder;
the beverage holder being integrated onto the lid; and
the beverage holder being oriented away from the insulated compartment.

10. The multifunctional insulated cooler apparatus as claimed in claim 1 comprising:
a divider plate;
the lateral wall comprising a front wall and a rear wall;
the divider plate being positioned within the insulated compartment; and
the divider plate being removably engaged with the front wall and the rear wall.

11. The multifunctional insulated cooler apparatus as claimed in claim 1 comprising:
a thermometer;
the thermometer being positioned within the insulated compartment; and
the thermometer being adjacently connected onto the lateral wall.

12. A multifunctional insulated cooler apparatus comprising:
an insulated compartment;
a lid;
a rechargeable battery;
at least one speaker system;
a short-range wireless data exchanging unit;
the insulated compartment comprising a base, a lateral wall, and an opening;
the lateral wall being perimetrically connected around the base;
the opening being delineated by the lateral wall, opposite of the base;
the lid being perimetrically attached to the lateral wall about the opening;
the rechargeable battery being mounted within the lid;
the speaker system being integrated into the lid;
the speaker system being electrically connected to the rechargeable battery;
the short-range wireless data exchanging unit being mounted within the lid;
the short-range wireless data exchanging unit being electrically connected to the rechargeable battery; and
the speaker system being electronically connected to the short-range wireless data exchanging unit.

13. The multifunctional insulated cooler apparatus as claimed in claim 12 comprising:
the lateral wall comprising a left wall, a right wall, a front wall, a rear wall, and a top edge;
the left wall being terminally connected to the base;
the right wall being terminally connected to the base;
the left wall and the right wall being oppositely positioned of each other about the base;
the front wall being terminally connected to the base, the left wall, and the right wall;
the rear wall being terminally connected to the base, the left wall, and the right wall;
the front wall and the rear wall being oppositely positioned of each other about the base;
the top edge being delimited by the left wall, the right wall, the front wall, and the rear wall; and
the lid being positioned atop the top edge.

14. The multifunctional insulated cooler apparatus as claimed in claim 13 comprising:
the front wall comprising a flat section and a curved section;
the flat section being terminally connected to the base, the left wall, and the right wall;
the curved section being terminally connected to the flat section, the left wall, and the right wall; and
the lid being positioned adjacent to the curved section.

15. The multifunctional insulated cooler apparatus as claimed in claim 12 comprising:
a power input;
a power output;
the power input being integrated into the lid;
the power output being integrated into the lid;
the power input being electrically connected to the rechargeable battery; and
the power output being electrically connected to the rechargeable battery.

16. The multifunctional insulated cooler apparatus as claimed in claim 12, wherein the speaker system is a full-range speaker system.

17. The multifunctional insulated cooler apparatus as claimed in claim 12, wherein the speaker system is a subwoofer speaker system.

18. The multifunctional insulated cooler apparatus as claimed in claim 12 comprising:
a left handle;
a right handle;
at least one beverage holder;
the left handle being integrated into a left wall of the lateral wall;
the right handle being integrated into a right wall of the lateral wall;
the beverage holder being integrated onto the lid; and
the beverage holder being oriented away from the insulated compartment.

19. The multifunctional insulated cooler apparatus as claimed in claim 12 comprising:
a divider plate;
the lateral wall comprising a front wall and a rear wall;
the divider plate being positioned within the insulated compartment; and
the divider plate being removably engaged with the front wall and the rear wall.

20. The multifunctional insulated cooler apparatus as claimed in claim 12 comprising:
a thermometer;
the thermometer being positioned within the insulated compartment; and
the thermometer being adjacently connected onto the lateral wall.
